(19) United States
(12) Patent Application Publication
(10) Pub. No.: US 2011/0073346 A1
(43) Pub. Date: Mar. 31, 2011

(54) GROUNDING MECHANISM FOR FOLDABLE ELECTRONIC DEVICES

(75) Inventor: ZHI-BIN OUYANG, Shenzhen (CN)

(73) Assignees: SHENZHEN FUTAIHONG PRECISION INDUSTRY CO., LTD., ShenZhen City (CN); FIH (HONG KONG) LIMITED, Kowloon (HK)

(21) Appl. No.: 12/771,266

(22) Filed: Apr. 30, 2010

(30) Foreign Application Priority Data
Sep. 30, 2009 (CN) 200910308037.X

(51) Int. Cl. H05K 5/02

(52) U.S. Cl. 174/51

(57) ABSTRACT

A grounding mechanism is used for a foldable electronic device including a barrel and an audio component. The grounding mechanism includes a connecting element and an elastic member. The connecting element is received in the barrel. The elastic member is attached to the audio component. One portion of the elastic member is electronically connected to the audio component, another portion of the elastic member electronically connected to the connecting element.

### BACKGROUND

1. Technical Field

The present disclosure relates to grounding mechanisms and, particularly, to a grounding mechanism used with a foldable electronic device.

2. Description of related art

Foldable electronic devices usually include a hinge for rotatably connecting a cover to a housing. In addition, an audio channel cover is usually disposed to the cover of the foldable electronic device. Electromagnetic interference and electrostatic charges are easily produced in the hinge and the audio channel cover when in use. A grounding mechanism is usually provided for conducting electromagnetic interference and electrostatic charges away from the hinge and the audio channel cover.

However, since the hinge and the audio channel cover may be at different positions depending upon their degrees of rotation, a conventional grounding structure of the foldable electronic device complicates the assembly process. In addition, conventional grounding structures, by increasing the volume of the foldable electronic device, can compromise requirements for the foldable electronic device to be compact.

Therefore, there is room for improvement within the art.

### BRIEF DESCRIPTION OF THE DRAWINGS

Many aspects of the grounding mechanism can be better understood with reference to the following drawings. The components in the drawings are not necessarily drawn to scale, the emphasis instead being placed upon clearly illustrating the principles of the present grounding mechanism. Moreover, in the drawings, like reference numerals designate corresponding parts throughout the several views.

FIG. 1 is an exploded, isometric view of one portion of a foldable electronic device using a grounding mechanism in accordance with an exemplary embodiment.

FIG. 2 is an enlarged view of an elastic member of FIG. 1.

FIG. 3 is a partially assembled, schematic view of the foldable electronic device.

FIG. 4 is an assembled, schematic view of the foldable electronic device.

FIG. 5 is a cross-sectional view of FIG. 4 along V-V line thereof.

### DETAILED DESCRIPTION

The present grounding mechanism may be applied in many different foldable electronic devices such as mobile phones, game devices, PDAs (personal digital assistant) and others. In an illustrated embodiment, the grounding mechanism is used in a foldable mobile phone.

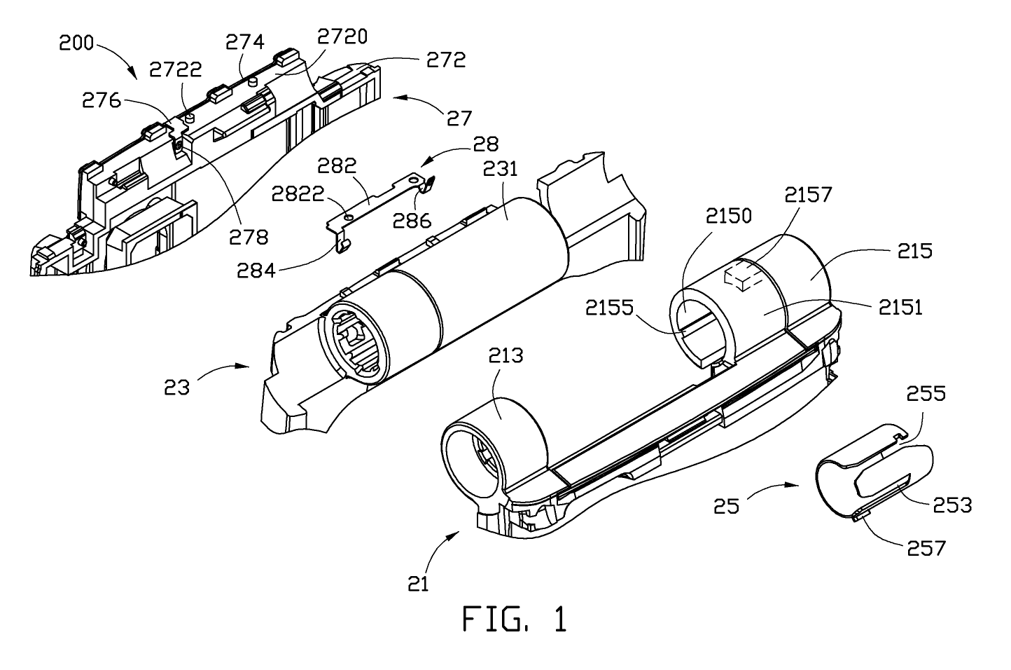

Referring to FIG. 1, the foldable mobile phone 200 includes a main body 21, a cover 23, a connecting element 25, an audio component 27, and an elastic member 28. The elastic member 28 conduct electromagnetic charges from the connecting element 25 and the audio component 27 to a ground pin of a printed circuit board (not shown) of the mobile phone 200.

The main body 21 includes a first barrel 213 at one end and an opposite second barrel 215 at another end thereof. The second barrel 215 defines a through hole 2150 surrounded by a circumferential wall 2151. A rib 2155 axially extends from an inner surface of the circumferential wall 2151. A slot 2157 is defined in the inner surface of the circumferential wall 2151.

The cover 23 has a shape substantially corresponding to the main body 21, and includes a sleeve portion 231 formed at one end thereof. The sleeve portion 231, the first barrel 213, and the second barrel 215 are configured for receiving a conventional hinge assembly (not shown) of the mobile phone 200 to rotatably connect the cover 23 to the main body 21.

The connecting element 25 is metal, and is configured for being received in the through hole 2150 of the second barrel 215. The connecting element 25 is used for conducting electromagnetic interference and electrostatic charges from the hinge assembly. The connecting element 25 is a hollow sleeve, and defines a first slit 253 and a second slit 255. The first slit 253 only communicates with one end of the connecting element 25 configured for receiving the rib 2155. The second slit 255 communicates with two ends of the connecting element 25 to allow the connecting element 25 to have an adjustable diameter due to the split configuration. A projection 257 extends from one end of the connecting element 25 for being received in the slot 2157.

The audio component 27 includes an audio base 272 and an audio cover 274. The audio base 272 includes a top surface 2720. Two posts 2722 project from the top surface 2720. The audio cover 274 is made of metal, and is positioned at one side of the audio base 272 adjacent to the top surface 2720. A tab 276 extends from one side of the audio cover 274 and rides the top surface 270. A protrusion 278 is formed on the tab 276.

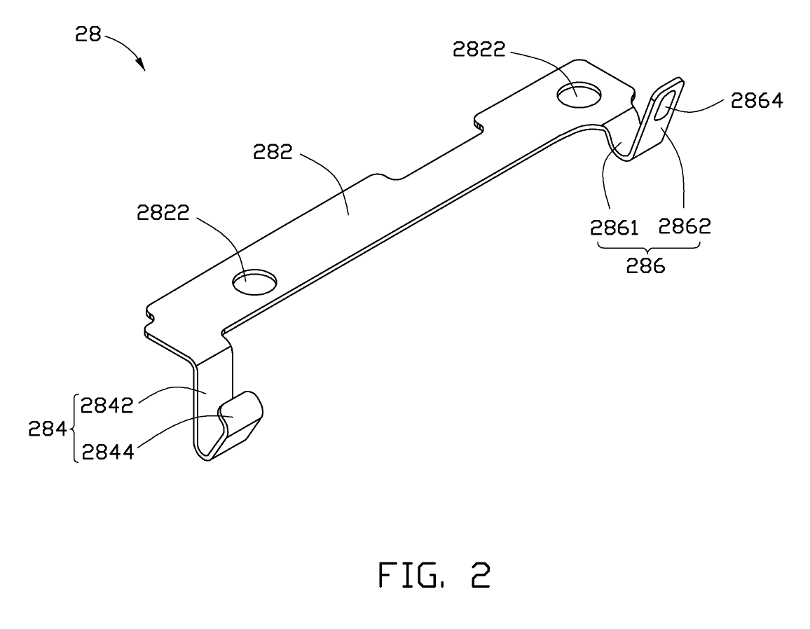

Referring to FIG. 2, the elastic member 28 is metal, and may be stamped or punched from a metal sheet. The elastic member 28 includes a main section 282. The main base 282 is substantially a long and narrow plate, and defines two post holes 2822 for receiving the posts 2722. A first bent portion 284 extends from one end of the main section 282. The first bent portion 284 includes a resisting end 2842 and a hooked end 2844. A second bent portion 286 extends from the other end of the main section 282. The second bent portion 286 includes an arcuate part 28621 and a holding part 2862. A contact 2864 is formed on the holding part 2862 for electronically connecting to the connecting element 25.

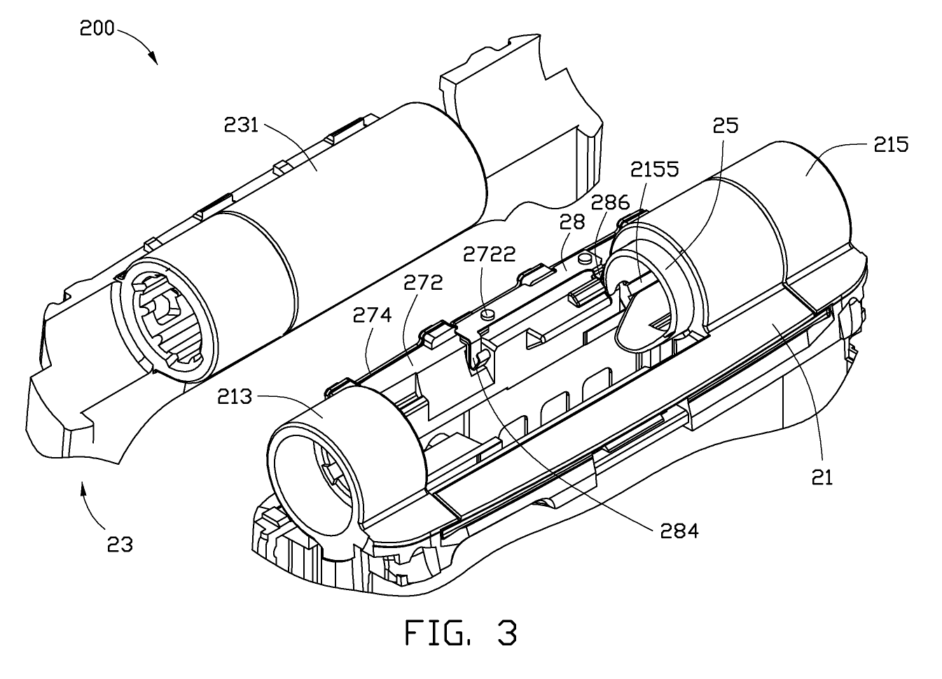

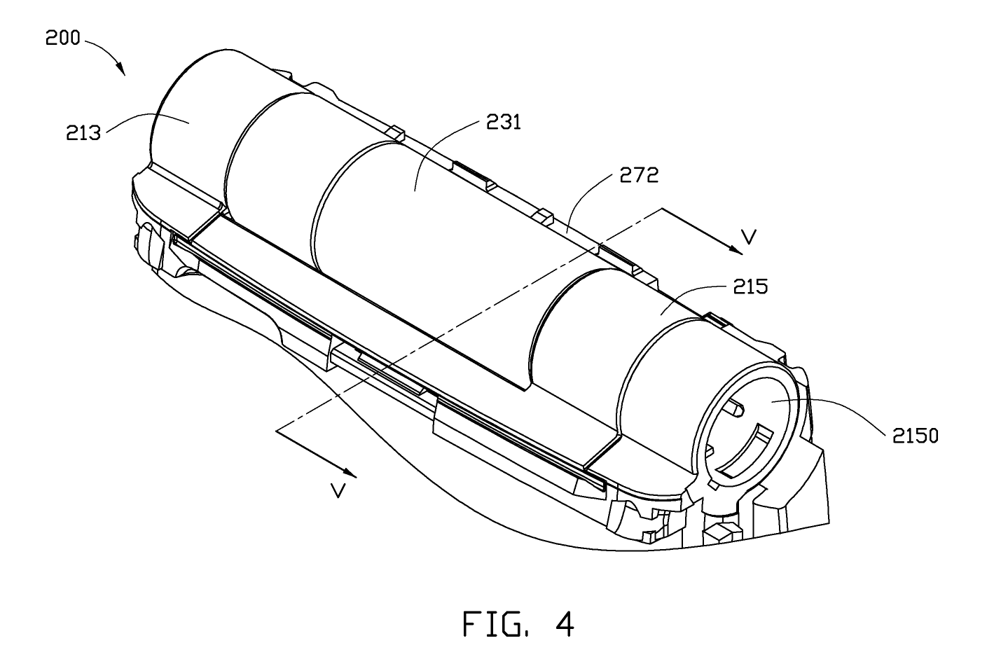

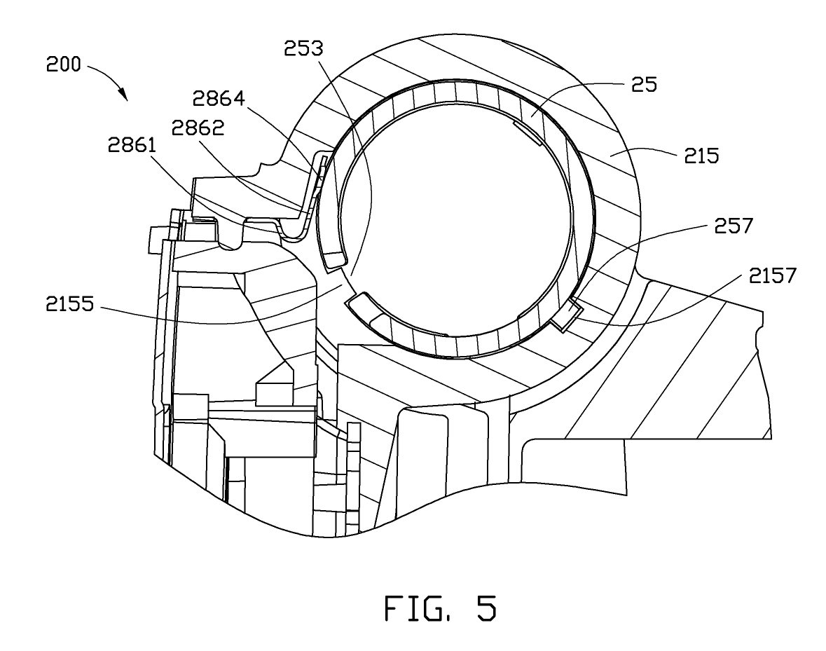

In assembly, referring to FIGS. 3 to 5, first, the post holes 2822 are placed around the posts 2722 of the audio base 272. The first bent portion 284 abuts the tab 276 to allow the protrusion 278 to be electronically connected to the elastic member 28. Then, the audio base 272 is attached to the main body 21. The connecting element 25 is received in the second barrel 215. The second slit 255 receives the rib 2153 and the projection 257 is received in the slot 2157 to allow the connecting element 25 to be fixed to the second barrel 215. One portion of the connecting element 25 is exposed from the second barrel 215 to allow the second bent portion 286 to be electronically connected to the connecting element 25. Finally, the sleeve portion 231 is positioned between the first barrel 213 and the second barrel 215. The cover 23 is rotatably connected to the main body 21. Therefore, the connecting element 25, the elastic member 28, and the audio cover 274 are electronically connected to a grounding pin of a main circuit board.

A significant advantage of the grounding mechanism is that the elastic member 28 is easily assembled to the main body 21. This simplifies assembly of the electronic device so that costs are reduced. In addition, space occupied in the interior of the electronic device is minimized.

It is to be understood, however, that even though numerous characteristics and advantages of the present disclosure have been set forth in the foregoing description, together with details of assembly and function, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A grounding mechanism for a foldable electronic device including a barrel and an audio component, the grounding mechanism comprising:
a connecting element received in the barrel;
an elastic member for attachment to the audio component, one portion of the elastic member for electronically connecting to the audio component, another portion of the elastic member electronically connected to the connecting element.

2. The grounding mechanism as claimed in claim 1, wherein the elastic member includes a main section, a first bent portion extends from one end of the main section, and a second bent portion extends from the other end of the main section.

3. The grounding mechanism as claimed in claim 2, wherein the main base is substantially a long and narrow plate, and defines two post holes.

4. The grounding mechanism as claimed in claim 2, wherein the second bent portion includes an arcuate part and a holding part, the holding part forms a contact resisting with the connecting element.

5. The grounding mechanism as claimed in claim 1, wherein the audio component includes an audio base and an audio cover, and two posts project from the audio base for fixing the elastic member.

6. The grounding mechanism as claimed in claim 5, wherein the audio cover is made of metal, and is positioned at one side of the audio base, a tab extends from one side of the audio cover, a protrusion is formed on the tab for abutting against the first bent portion.

7. The grounding mechanism as claimed in claim 1, wherein the connecting element is metal, and the barrel defines a through hole configured for receiving the connecting element.

8. An electronic device comprising:
a main body;
an audio component attached to the main body;
a connecting element attached to the main body;
an elastic member attached to the audio component, one portion of the elastic member electronically connected to the audio component, another portion of the elastic member electronically connected to the connecting element.

9. The electronic device as claimed in claim 8, wherein the main body includes a first barrel at one end and an opposite second barrel at another end thereof, the second barrel defines a through hole, and the connecting element is received in the through hole.

10. The electronic device as claimed in claim 8, wherein the audio component includes an audio base and an audio cover, two posts project from the audio base.

11. The electronic device as claimed in claim 10, wherein the audio cover is made of metal, and is positioned at one side of the audio base, a tab extends from one side of the audio cover, and a protrusion is formed on the tab for abutting against the first bent portion.

12. The electronic device as claimed in claim 8, wherein the elastic member includes a main section, a first bent portion extends from one end of the main section, a second bent portion extends from the other end of the main section.

13. The electronic device as claimed in claim 12, wherein the main base is substantially a long and narrow plate, and defines two post holes, the second bent portion includes an arcuate part and a holding part, the holding part forms a contact resisting with the connecting element.
